(19) United States
(12) Patent Application Publication
(10) Pub. No.: US 2022/0028732 A1
(43) Pub. Date: Jan. 27, 2022

(54) PROCESS FOR PREPARING EPITAXY WAFER AND EPITAXY WAFER THEREFROM

(71) Applicant: Zing Semiconductor Corporation, Shanghai (CN)

(72) Inventors: Huajie Wang, Shanghai (CN); Gongbai Cao, Shanghai (CN); Chihhsin Lin, Shanghai (CN)

(73) Assignee: Zing Semiconductor Corporation, Shanghai (CN)

(21) Appl. No.: 17/123,621

(22) Filed: Dec. 16, 2020

(51) Int. Cl. H01L 21/762; C30B 25/18; H01L 21/768

(52) U.S. Cl. CPC H01L 21/76297; H01L 21/76826; H01L 21/76828; C30B 25/18

(57) ABSTRACT

The present application provides a process for preparing an epitaxy wafer, and an epitaxy wafer prepared therefrom. The process comprises: step S1: providing a semiconductor substrate wafer, conducting an epitaxy process and forming an epitaxy layer on the wafer; and step S2: conducting a thermal treatment to the wafer to eliminate the haze pattern of the epitaxy layer. According to the process, the thermal treatment after the epitaxy process can facilitate the orientation of atoms on the wafer surface toward the lowest energy orientation, so that the atoms of the epitaxy layer arrange and accumulate uniformly. Therefore, the haze pattern on the wafer surface can be eliminated.

### BACKGROUND OF THE INVENTION

### 1. Field of the Invention

The present application relates to the semiconductor technical field, and more particularly to manufacture of epitaxy wafer.

### 2. Description of the Related Art

Epitaxy process is widely applied to manufacture of semiconductor integrated circuits. Epi-wafer is the basic material for manufacture of integrated circuit chip. To prepare epi-wafer, it needs to grow the epitaxy layer at high temperature of about 1100° C.

In a typical process for preparing epi-wafer, the wafer is grabbed by blowing wand that is able to grab and place wafers under high temperature and increase yield. However, the significant haze patterns are formed in the blowing area of the wafer surface caused by the blowing air of the wand with various factors of the epitaxy process, that affect the mass distribution of epitaxy layer, and further adversely affect quality of the following manufactured devices, especially the high level logic device.

The present application provides a process for preparing an epitaxy wafer and an epitaxy wafer prepared therefrom to solve the conventional technical problems.

### SUMMARY

In the summary of the invention, a series of concepts in a simplified form is introduced, which will be described in further detail in the detailed description. This summary of the present invention does not intend to limit the key elements or the essential technical features of the claimed technical solutions, nor intend to limit the scope of the claimed technical solution.

To solve the problems of conventional technologies, the present application provides a process for preparing an epitaxy wafer comprising:

step S1: providing a semiconductor substrate wafer, conducting an epitaxy process and forming an epitaxy layer on the wafer; and
step S2: conducting a thermal treatment to the wafer to eliminate the haze pattern of the epitaxy layer.

In one embodiment, the thermal treatment in the step S2 is a rapid thermal treatment to rapidly increase the wafer temperature to the desired temperature of the thermal treatment to anneal.

In one embodiment, the desired temperature of the thermal treatment is 1000° C. to 1200° C.

In one embodiment, the thermal treatment is conducted for 1 minute (min) to 10 min.

In one embodiment, in the step S1, the substrate wafer is provided via blowing wand for the epitaxy process.

In one embodiment, the process further comprises conducting a metrology test to the substrate wafer for determination of morphology on the wafer surface after the step S1, before the step S2, and/or after the step S2.

In one embodiment, in the step S2, the substrate wafer is grabbed by mechanical means.

In one embodiment, in the step S2, the thermal treatment is conducted for plural substrate wafers simultaneously.

In one embodiment, the thermal treatment is under an atmosphere of a gas, and the gas does not react with the substrate wafer.

Further, the present application provides an epitaxy wafer, which is prepared by any of the processes described above.

### BRIEF DESCRIPTION OF THE DRAWINGS

FIG. 1 shows, in accordance with an embodiment of the present application, a flow chart of the process for preparing an epitaxy wafer.

FIG. 2 shows, in accordance with an embodiment of the present application, the temperature change with the time during the thermal treatment.

FIGS. 3A-3D show comparison of metrology test results between the wafers prepared by the process of the present application and by the conventional process.

### DETAILED DESCRIPTION OF THE EMBODIMENTS

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

For a thorough understanding of the present invention, the detailed steps will be set forth in detail in the following description in order to explain the technical solution of the present invention. The preferred embodiments of the present invention is described in detail as follows, however, in addition to the detailed description, the present invention also may have other embodiments.

The terminology used herein is for the purpose of describing particular example embodiments only and is not intended to be limiting. As used herein, the singular forms may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

It should be understood that the present invention may be practiced in different forms and that neither should be construed to limit the scope of the disclosed examples. On the contrary, the examples are provided to achieve a full and complete disclosure and make those skilled in the art fully receive the scope of the present invention. In the drawings, for clarity purpose, the size and the relative size of layers and areas may be exaggerated. In the drawings, same reference number indicates same element.

To solve the problems of conventional technologies, the present application provides a process for preparing an epitaxy wafer comprising:

step S1: providing a semiconductor substrate wafer, conducting an epitaxy process and forming an epitaxy layer on the wafer; and
step S2: conducting a thermal treatment to the wafer to eliminate the haze pattern of the epitaxy layer.

According to the process for preparing an epitaxy wafer, the thermal treatment after the epitaxy process can facilitate the orientation of atoms on the wafer surface toward the lowest energy orientation. Therefore, the atoms of the epitaxy layer arrange and accumulate uniformly in the blow area and the non-blow area on the wafer surface, and the haze pattern on the wafer surface can be eliminated.

### EXAMPLES

### Example 1

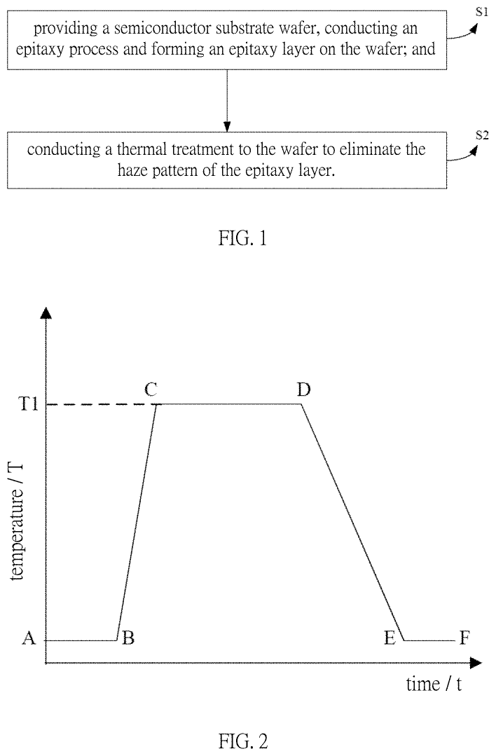

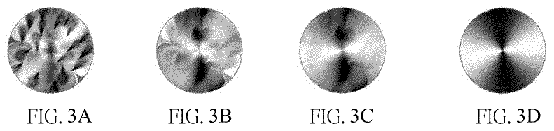

The process of the present application is described by referring FIG. 1, FIG. 2 and FIGS. 3A-3D. FIG. 1 shows, in accordance with an embodiment of the present application, a flow chart of the process for preparing an epitaxy wafer. FIG. 2 shows, in accordance with an embodiment of the present application, the temperature change with the time during the thermal treatment. FIGS. 3A-3D show comparison of metrology test results between the wafers prepared by the process of the present application and by the conventional process.

First, referring FIG. 1, it conducts step S1: providing a semiconductor substrate wafer, conducting an epitaxy process and forming an epitaxy layer on the wafer.

The epitaxy process is to form a thin single crystal layer on a single crystal substrate, thereby, an epitaxy wafer (EPI wafer) is manufactured.

In the epitaxy wafer manufacture, a substrate wafer is processed firstly, and the substrate wafer is generally a polished wafer. For example, the substrate wafer includes sapphire wafers, silicon carbide wafers and silicon wafers. The substrate wafer can be prepared by slicing a crystal ingot and conducting post-treatment. The post-treatment comprises: placing the wafer obtained by slicing the ingot in a boiler tube, heating the wafer under an inert gas atmosphere, rapidly cooling in air to remove oxygen impurities and stabilize electric resistance. An apparatus of rapid thermal process is needed for the post-treatment. The wafer is then polished by a polishing machine and cleaned by a wafer cleaning machine. Accordingly, the substrate wafer is prepared.

In one embodiment, before the epitaxy process, the wafer is subjected to a pre-treatment.

In one embodiment, the pre-treatment comprises washing, purging, and the like, which is not limited herein.

In one embodiment, the substrate wafer is silicon wafer, and a thin silicon layer grows on the substrate wafer via the epitaxy process of the step S1.

To avoid contamination of the substrate wafer, it generally transfers the substrate wafer via blowing wand to the epitaxy furnace. The significant haze patterns are formed in the blowing area of the wafer surface caused by the blowing air of the wand with various factors of the epitaxy process. Such haze patterns reduce the wafer gloss, affect the mass distribution of epitaxy layer, and affect the quality of the manufactured device, especially the high level logic device.

The present application is to solve the problem of the haze patterns on the substrate wafer. Continuously referring FIG. 1, the process is described as follows.

Continuously referring FIG. 1, it conducts step S2: conducting a thermal treatment to the wafer to eliminate the haze pattern of the epitaxy layer.

Temperature of the epitaxy process affects the distribution of the haze pattern. The higher temperature makes more significant haze patterns, because the atoms on the surface of the substrate wafer are moved by large volume gas flow under the high temperature. In order to rearrange the atoms, a thermal treatment is applied to the substrate wafer after the epitaxy process in the present application. The thermal treatment promotes the atom orientation on the wafer surface toward the lowest energy orientation. Therefore, the arrangement and accumulation of atoms are consistent in wand area and non-wand area on the substrate wafer surface, and the haze patterns on the substrate wafer surface can be eliminated accordingly.

In one embodiment, the thermal treatment is a rapid thermal treatment to rapidly increase the wafer temperature to the desired temperature of the thermal treatment to anneal. In the rapid thermal treatment, the substrate wafer is heated to rapidly achieve the desired temperature, the desired temperature of the substrate wafer is maintained for a period of time, then the substrate wafer is cooled rapidly. Because the temperature of the substrate wafer surface elevates rapidly, the atoms can sufficiently rearrange to eliminate the haze patterns.

In one embodiment, the thermal treatment temperature is 1000° C. to 1200° C.

In one embodiment, the thermal treatment time is 1 minute (min) to 10 min, which means the time to maintain the thermal treatment temperature.

In one embodiment, a gas which does not react with the substrate wafer can be applied to the thermal treatment. In one embodiment, the gas includes, but not be limited to, hydrogen, nitrogen and/or argon.

In one embodiment, in the step S2, the thermal treatment is conducted at 1100° C.-1300° C. for 1-2 min under hydrogen atmosphere.

Referring FIG. 2, the diagram illustrates the temperature change with the time during the thermal treatment in accordance with one embodiment of the present application.

As shown in FIG. 2, in AB section, the substrate wafer completing the epitaxy process loads in the thermal treatment furnace. In BC section, the thermal treatment furnace has an elevated temperature to a thermal treatment temperature T1. During this period, the substrate wafer surface enters the state of thermal treatment while the temperature increases rapidly. In CD section, the substrate wafer maintains at the thermal treatment temperature T1 for a time period to sufficiently rearrange the atoms of the substrate wafer surface to totally eliminate the haze patterns. Finally, in DE section, the substrate wafer is cooled to ambient temperature to load out.

In one embodiment, during the load in (AB section) and load out (ED section), the substrate wafer is grabbed by mechanical means. It further prevents the substrate wafer from formation of haze area by gas grabbing.

In one embodiment, in the step S2, the thermal treatment can be conducted to single substrate wafer or to plural substrate wafers simultaneously.

In one embodiment, before the above thermal treatment, a metrology test is applied to the substrate wafer to determine the morphology. The morphology of the substrate wafer includes, but is not limited to, surface gloss, granularity, flatness and the like.

In one embodiment, after the above thermal treatment, a metrology test is applied to the substrate wafer to determine the morphology. The morphology of the substrate wafer includes, but is not limited to, surface gloss, granularity, flatness and the like.

Further, in one embodiment, if the haze pattern still exists on the substrate wafer surface after the thermal treatment and the metrology test, the step S2 can be conducted repeatedly until complete elimination of the haze pattern.

In one embodiment, after the metrology test, the routine steps such as purge, and the following sorting and packing steps can be conducted.

Referring FIGS. 3A-3D, they show comparison of metrology test (haze map) results between the wafers prepared by the process of the present application and by the conventional process. FIG. 3A, FIG. 3B and FIG. 3C show the metrology test results of the wafers prepared by the conventional process, which have the worse gloss and the haze patterns on the wafer surface. In contrast, FIG. 3D shows that the wafer prepared by the present application has excellent surface gloss and no haze pattern. Accordingly, the process of the present application is able to completely eliminate the haze patterns on the substrate wafer surface.

The exemplary illustration of the process of the present application is provided as above. According to the process for preparing an epitaxy wafer in the present application, the thermal treatment after the epitaxy process can facilitate the orientation of atoms on the substrate wafer surface toward the lowest energy orientation. Therefore, the atoms of the epitaxy layer can rearrange and accumulate uniformly on the wafer surface, and the haze pattern on the wafer surface can be eliminated.

### Example 2

The present application further provides an epitaxy wafer prepared by the process as described in Example 1.

According to the process for preparing an epitaxy wafer in the present application, the thermal treatment after the epitaxy process can facilitate the orientation of atoms on the wafer surface toward the lowest energy orientation. Therefore, the atoms of the epitaxy layer rearrange and accumulate uniformly on the wafer surface, and the haze pattern on the wafer surface is eliminated. Accordingly, the epitaxy wafer of the present application has advantages such as no haze pattern on wafer surface, no haze defect, and the good mass distribution of epitaxy layer, so that the quality of the following manufactured device, especially the high level logic device can be guaranteed.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims and its equivalent systems and methods.

What is claimed is:

1. A process for preparing an epitaxy wafer comprising:
step S1: providing a semiconductor substrate wafer, conducting an epitaxy process and forming an epitaxy layer on the wafer; and
step S2: conducting a thermal treatment to the wafer to eliminate the haze pattern of the epitaxy layer.

2. The process of claim 1, wherein the thermal treatment in the step S2 is a rapid thermal treatment to rapidly increases the wafer temperature to the desired temperature of the thermal treatment to anneal.

3. The process of claim 2, wherein the desired temperature of the thermal treatment is 1000° C. to 1200° C.

4. The process of claim 2, wherein the thermal treatment is conducted for 1 minute (min) to 10 min.

5. The process of claim 1, wherein, in the step S1, the substrate wafer is provided via blowing wand for the epitaxy process.

6. The process of claim 1 further comprising, conducting a metrology test to the substrate wafer for determination of morphology on the wafer surface after the step S1, before the step S2, and/or after the step S2.

7. The process of claim 1, wherein, in the step S2, the substrate wafer is grabbed by mechanical means.

8. The process of claim 1, wherein, in the step S2, the thermal treatment is conducted for plural substrate wafers simultaneously.

9. The process of claim 1, wherein the thermal treatment is under an atmosphere of a gas, and the gas does not react with the substrate wafer.

10. An epitaxy wafer, which is prepared by the process of claim 1.
